(19) United States
(12) Patent Application Publication
(10) Pub. No.: US 2002/0079937 A1
(43) Pub. Date: Jun. 27, 2002

(54) Digital delay locked loop with wide dynamic range and fine precision

(76) Inventor: Thucydides Xanthopoulos, Charlestown, MA (US)

Correspondence Address: CONLEY ROSE & TAYON, P.C., P. O. BOX 3267, HOUSTON, TX, 77253-3267, US

(21) Appl. No.: 09/947,028

(22) Filed: Sep. 5, 2001

Related U.S. Application Data
(60) Provisional application No. 60/230,078, filed on Sep. 5, 2000.

(51) Int. Cl. H03L 7/06

(52) U.S. Cl. 327/158; 327/277

(57) ABSTRACT

A delay-locked loop includes two delay lines. One line provides variable coarse delay adjustments, while the other delay provides variable fine delay adjustments. By providing two delay lines—one coarse and one fine—the dual delay line configuration of the preferred DLL allows the DLL to exhibit a wide dynamic range to accommodate large on-chip process delay deviations among the clocks to be matched and at the same time exhibit fine-grain delay settings to enable accurate phase matching between the clocks.

### CROSS-REFERENCE TO RELATED APPLICATIONS

This application is a non-provisional application claiming priority to provisional application Serial No. 60/230,078, filed on Sep. 5, 2000, entitled “All Digital Delay-Locked Loop With Wide Dynamic Range And Fine Precision,” the teachings of which are incorporated by reference herein.

### STATEMENT REGARDING FEDERALLY SPONSORED RESEARCH OR DEVELOPMENT

Not applicable.

### BACKGROUND OF THE INVENTION

1. Field of the Invention

The present invention relates generally to delay-locked loops. More particularly, the invention relates to a digital delay-locked loop having wide dynamic range and fine precision.

2. Background of the Invention

In synchronous electronic systems, the integrated circuits in the system are synchronized to a common reference clock. This synchronization often cannot be achieved simply by distributing a single reference clock to each of the integrated circuits for the following reason, among others. When an integrated circuit receives a reference clock, the circuit often must condition the reference clock before the circuit can use the clock. For example, the circuit may buffer the incoming reference clock or may convert the incoming clock from one voltage level to another. This processing introduces its own delay, with the result that the processed reference clock, which will be referred to as a local clock, often will no longer be adequately synchronized with the incoming reference clock. The trend towards faster system clock speeds further aggravates this problem since faster clock speeds reduce the amount of delay, or clock skew, which can be tolerated.

To remedy this problem, an additional circuit is typically used to synchronize the local clock to the reference clock. Two common circuits which are used for this purpose are the phase-locked loop (PLL) and the delay-locked loop (DLL). In the phase-locked loop, a voltage-controlled oscillator produces the local clock. The phases of the local clock and the reference clock are compared by a phase-frequency detector, with the resulting error signal used to drive the voltage-controlled oscillator via a loop filter. The feedback via the loop filter phase locks the local clock to the reference clock. Stability of the feedback loop, however, depends in part on the loop filter. The electronic characteristics of the loop filter, in turn, often depend significantly on manufacturing parameters. As a result, the same loop filter design may result in a stable feedback loop when manufactured with one process but an unstable loop when manufactured by another. It is difficult to produce a single loop filter design for use with all manufacturing processes, and the design of the loop filter typically must be optimized on a process by process basis.

The delay-locked loop generates a synchronized local clock by delaying the incoming reference clock by an integer number of clock periods. More specifically, the buffers, voltage level converters, etc. of the integrated circuit introduce a certain amount of delay. The delay-locked loop introduces an additional amount of delay such that the resulting local clock is synchronous with the incoming reference clock. This approach avoids the stability problem inherent in the phase-locked loop approach. Delay-locked loops, however, have a disadvantage of narrow dynamic range relative to their precision. That is, a highly accurate DLL requires that the two clock signals being synchronized have a phase difference that is relatively small. On the other hand, conventional DLLs can be made to synchronize clocks with a larger phase difference, but the resulting accuracy decreases and may be less than desirable.

Accordingly, there is a need for an improved DLL device which synchronizes local clocks to reference clocks, and which provides a wider dynamic range of operation with acceptable precision.

### BRIEF SUMMARY OF THE INVENTION

The problems noted above are solved in large part by a delay-locked loop (DLL) that has the capability to match the phase of one clock to that of a reference clock. The preferred delay locked loop is primarily digital and uses a dual delay-line architecture. One delay line is used for coarse phase adjustments and the other delay line is used for fine adjustments. The dual delay line configuration allows the DLL to exhibit a wide dynamic range to accommodate large on-chip process delay deviations among the clocks to be matched, and at the same time exhibit fine-grain delay settings to enable accurate phase matching among the clocks.

The coarse delay line comprises 64 inverter stages with equally spaced multiplexer taps (16), whereas the fine line is formed by 8 stages of multiple-fingered inverters with optimized transistor sizes for maximum linearity. The number of coarse taps (and the dynamic range) can be extended without changing the DLL control structures. The DLL is controlled by a Finite State Machine (FSM) controller during two separate stages of phase acquisition. After the assertion of a reset signal, the controller tests multiple coarse line taps (starting at the fastest setting) and selects the first tap which results in a derived clock edge placement that produces a negative phase error less than the coarse tap delay. When this event occurs (detected by a fast/slow transition at the phase detector), the controller freezes the coarse setting and enters the second stage of lock acquisition. The fine delay line is then activated and its setting is stored in a bidirectional shift register under the control of a phase detector. The fine delay line will eventually bring the two clocks in phase lock and maintain such condition in the presence of slow voltage and temperature variations. An 8-stage Johnson counter may be used to reduce a thermometer code update rate to guarantee stability in the presence of considerable feedback loop delay.

As noted above, the preferred embodiment of the DLL is mostly digital and thus contains few or no analog components. In this way the DLL can be ported easily between processes and it is less susceptible to adverse operating conditions and process variations. Also, the DLL contains a single loop (albeit with two serial delay lines) as opposed to a dual loop in many conventional DLL designs, thus making the preferred DLL design of this disclosure simpler and easier to implement. In addition, the DLL's lock acquisition mechanism is designed such that a lock can always be achieved if the initial phase error between the clocks to be matched is smaller that the (quite large) dynamic range of the system. The DLL is unlikely ever to chase the wrong clock edge, a problem which characterizes various conventional designs. Conventional designs, instead, would have to guarantee that wrong edges will not be chased through artificial reduction of the dynamic range of the system. The present design provides this guarantee through a digital controller that enhances the operation of the phase detector. Further, although the dynamic range of the present DLL is not infinite, it is substantially scalable and can be extended without rendering the implementation impractical.

These and other advantages will become apparent upon reviewing the following description and accompanying drawings.

### BRIEF DESCRIPTION OF THE DRAWINGS

For a detailed description of the preferred embodiments of the invention, reference will now be made to the accompanying drawings in which:

FIG. 1 shows an electronic system showing the use of the improved delay-locked loop of the preferred embodiment;

FIG. 2 shows a block diagram of the delay-locked loop which includes a coarse delay line and a fine delay line;

FIG. 3 shows more detail regarding the coarse delay line;

FIG. 4 shows more detail regarding the fine delay line; and

FIG. 5 illustrates the operation of the delay-locked loop to synchronize the phase of two clock signals.

### NOTATION AND NOMENCLATURE

Certain terms are used throughout the following description and claims to refer to particular system components. As one skilled in the art will appreciate, computer companies may refer to a component and sub-components by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either a direct or indirect electrical connection. Thus, if a first device couples to a second device, that connection may be through a direct electrical connection, or through an indirect electrical connection via other devices and connections. To the extent that any term is not specially defined in this specification, the intent is that the term is to be given its plain and ordinary meaning.

### DETAILED DESCRIPTION OF THE PREFERRED EMBODIMENTS

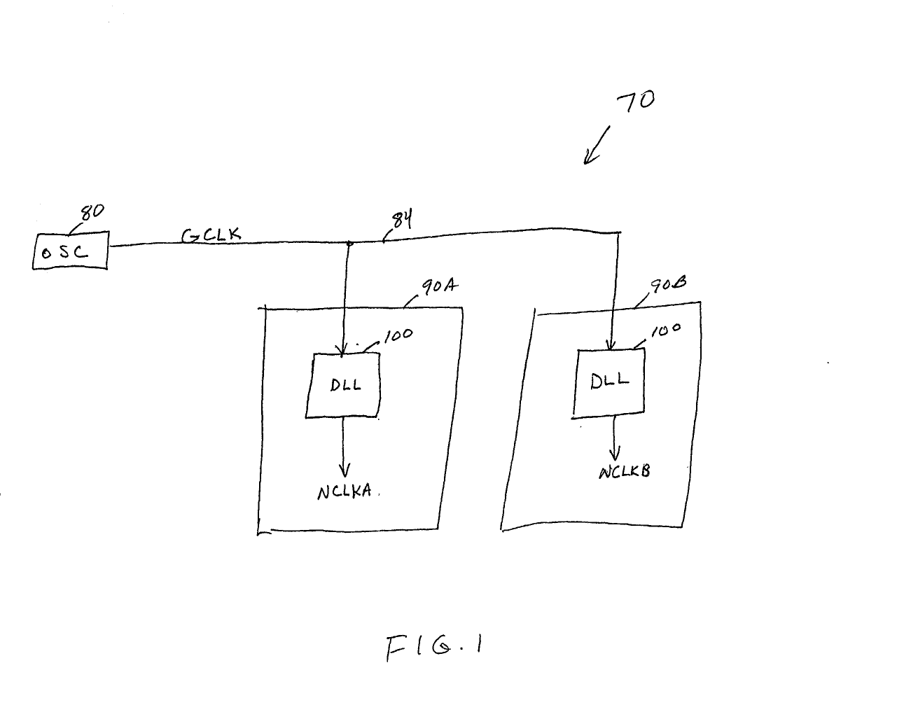

Referring now to FIG. 1, a block diagram of an electronic system 70 is shown in accordance with a preferred embodiment of the invention. The system 70 includes an oscillator 80 and one or more integrated circuits (ICs) 90A and 90B. The integrated circuits 90A and 90B may comprise microprocessors or other types of devices. Further, integrated circuits 90A and 90B may be fabricated on separate dies or on the same die as part of the same IC package. As such, circuits 90A and 90B may comprise different logic circuits within the same microprocessor. As shown, each integrated circuit 90A, 90B may contain a clock generator 100, which in accordance with the preferred embodiment of the invention comprises a delay-locked loop.

Each integrated circuit 90A and 90B receives a reference clock signal (GCLK) from the oscillator 80 over signal line 84. Within each integrated circuit 90A and 90B, the DLL 100 receives the reference clock (GCLK) and generates a clock signal that is local to each integrated circuit. The local clocks are labeled in FIG. 1 as NCLKA and NCLKB.

Each integrated circuit 90A and 90B performs one or more functions using a local clock (NCLK) that is derived from the input reference clock (GCLK). Typically, the integrated circuit will process the incoming clock signal to generate the local clock. This processing may include functions such as buffering, amplification, or conversion between various voltage levels. The circuits (not specifically shown) which perform this processing generally introduce a delay, or clock skew, to the incoming reference clock. The local clock that is processed from the reference clock, therefore, typically will not be synchronized with the incoming reference clock. This asynchronism can detrimentally effect the performance of the integrated circuit. To solve this problem, the clock generators 100 compensate for the clock skews introduced by the processing circuitry.

In accordance with the preferred embodiment of the invention, therefore, electronic system 70 operates with each of the local NCLKs synchronized to the reference GCLK. To that end, the DLLs 100 ensure that the local clocks they generate are synchronous with the respect to the reference GCLK received on line 84.

FIG. 1 depicts the synchronization of separate integrated circuits 90A and 90B to a common reference clock. Those of ordinary skill in the art, however, will recognize that the preferred embodiment is not limited to the synchronization of integrated circuits. For example, the clock synchronization technique described herein may be used to synchronize circuit boards or multi-chip modules to one another. Alternately, the present technique may be used in multiple locations on a single integrated circuit in order to synchronize multiple local clocks to the reference clock. The preferred embodiment also should not be limited to systems in which multiple local clocks are synchronized to a single reference clock, as is depicted in FIG. 1. For example, each local clock may be synchronized to a different reference clock or even to other local clocks.

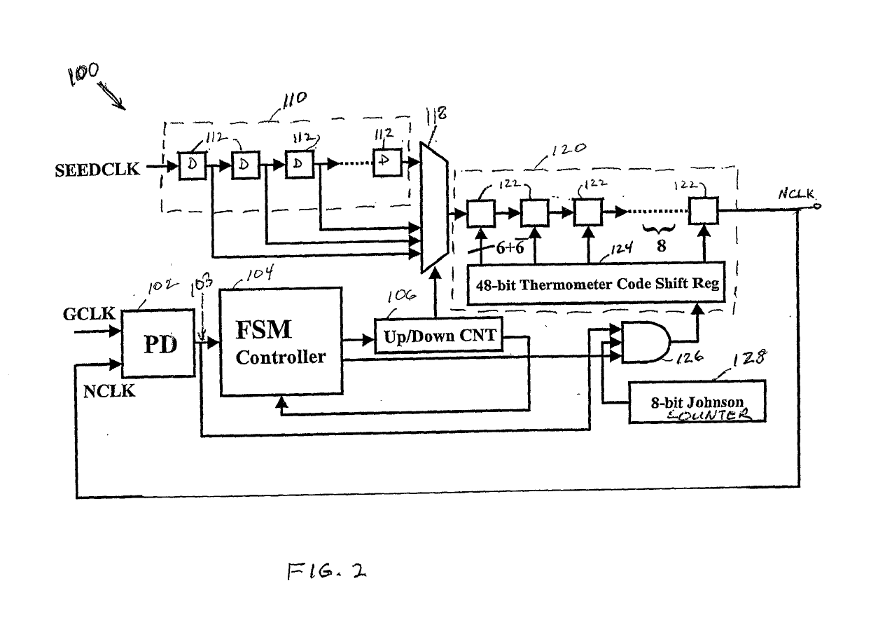

An exemplary embodiment of the preferred DLL 100 is shown in FIG. 2. As shown in FIG. 2, DLL 100 preferably includes a phase detector 102, a controller 104 (which may comprise, for example, a finite state machine), an up/down counter 106, a coarse delay line 110, a multiplexer 118, fine delay line 120, a logic gate 126 and an 8-stage counter 128. The coarse delay line 110 receives a seed clock (SEEDCLK) as an input signal. The seed clock comprises a clock of substantially the same frequency as GCLK and preferably is generated by an oscillator (not shown) that is part of the DLL 100 or a separately provided in the integrated circuit in which the DLL is located. Although the seed clock has substantially the same frequency as the reference GCLK, the seed clock may be out of phase with respect to GCLK. The seed clock is provided the coarse delay 110 which, in turn, couples to the multiplexer 118. From there, the coarsely delayed seed clock is further delayed by the fine delay 120 to produce the NCLK as shown. The DLL 100 thus functions to produce a delayed version of the seed clock (the NCLK signal) to thereby synchronize the seed clock to the reference GCLK and substantially eliminate the phase difference. That is, the DLL 100 introduces a delay to the seed clock to produce the NCLK, and the NCLK and the reference GCLK will have substantially no phase difference with respect to each other.

Each of the delay lines 110 and 120 are capable of providing a variable delay. In general, the coarse delay 110 is capable of introducing delays in relatively large increments with respect to the fine delay 120 which is capable of changing the amount of delay by relatively small increments. By providing two delay lines—one coarse and one fine—the dual delay line configuration of the preferred DLL 100 allows the DLL to exhibit a wide dynamic range to accommodate large on-chip process delay deviations among the clocks to be matched and at the same time exhibit fine-grain delay settings (e.g., less than 10 picoseconds) to enable accurate phase matching between the clocks.

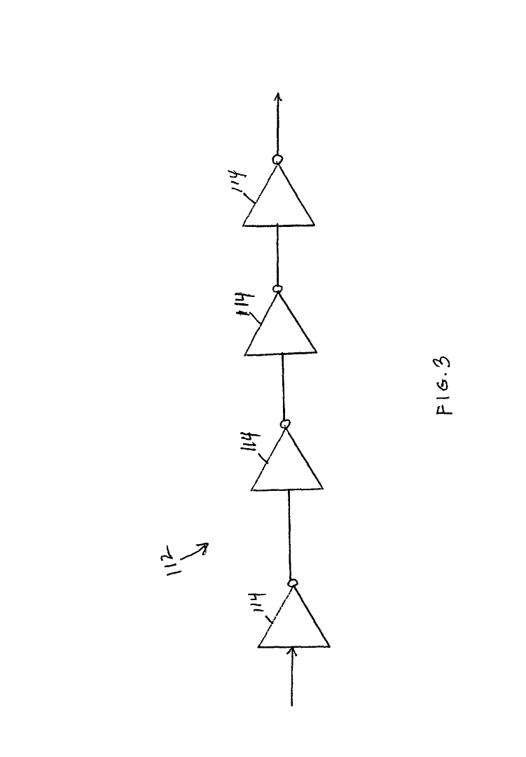

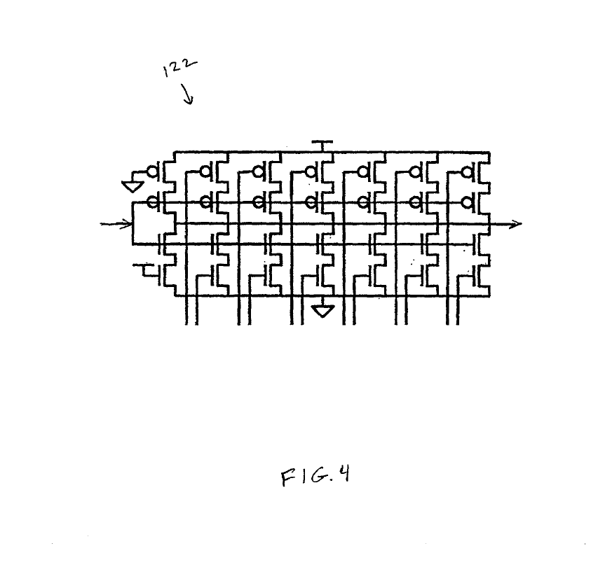

The construction of the delay lines 110 and 120 will be briefly described with respect to FIGS. 2-4. Referring to FIGS. 2 and 3, the coarse delay 110 preferably comprises a multi-tap delay line. In accordance with one suitable embodiment the multi-tap delay line includes 16 delay elements 112 as shown in FIG. 2. The preferred construction of each delay element 112 is shown in FIG. 3 as comprising four serially connected inverter stages 114. Thus, coarse delay 110 in accordance with a preferred embodiment includes 64 inverter stages with 16 equally spaced multiplexer taps. Each tap is taken from the output of a delay element 112 and provided as an input to the multiplexer 118. Referring now to FIGS. 2 and 3, the fine delay line 120 is formed by eight stages 122 of multiple-fingered inverters as shown in FIG. 4 preferably with optimized transistor sizes for maximum linearity. The fine delay line 120 also includes a 48-bit thermometer code shift register 124 in accordance with the preferred embodiment.

The operation of DLL 100 will now be described in greater detail. The output clock signal NCLK is fed back to the phase detector 102 which also receives the input reference GCLK as an input signal. In accordance with known techniques, phase detector 102 determines the phase difference between the GCLK and NCLK signals. The difference in phase between GCLK and NCLK is provided as an output error signal on line 103 to the controller 104. The error signal on line 103 encodes whether there is a non-zero difference in phase between GCLK and NCLK and, if so, the amount of phase difference.

The DLL 100 preferably is controlled by the FSM controller 104 during two separate stages of phase acquisition. After the assertion of a DLL reset signal (not specifically shown), the controller 104 tests the multiple coarse line taps preferably starting at the fastest setting (i.e., least amount of delay) and selects the first tap which results in a derived clock edge placement that produces a negative phase error less than the coarse tap delay. By “testing,” it is meant that the controller controls the up/down counter 106, which provides a control selection signal to the multiplexer 118, to select a seed clock output from the multiplexer 118 corresponding to each possible delay from the coarse delay 110. When the aforementioned event occurs (detected by a fast/slow transition at the phase detector), the FSM controller 104 freezes the coarse setting and enters the second stage of lock acquisition.

In the second stage, the fine delay line 120 is activated and its setting is stored in the bi-directional shift register 124 under the control of the phase detector 102. The fine delay line 120 will eventually bring the two clocks (GLCK and NCLK) in phase lock and maintain such condition in the presence of slow voltage and temperature variations. The 8-stage Johnson counter 128 preferably is used to reduce the thermometer code update rate to guarantee stability in the presence of considerable feedback loop delay.

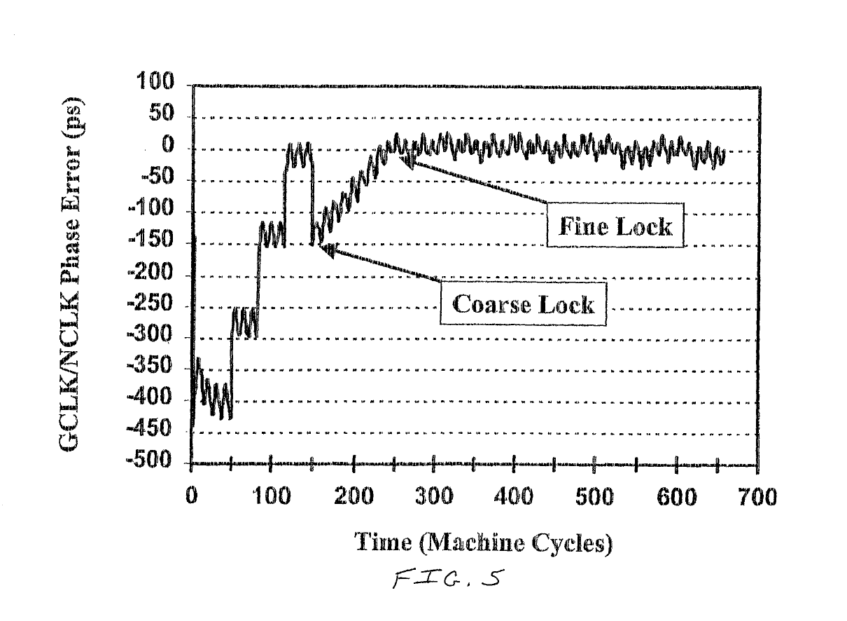

The 2-stage lock acquisition process of the preferred embodiment is clearly visible from the phase error plot of FIG. 5. In the example of FIG. 5, the FSM controller 104 locks at the third coarse tap after four steps towards slower taps and one step towards faster taps to ensure coarse lock at a small negative phase error. The fine delay line 120 completes the lock acquisition at the location indicated on the graph and maintains such state with continuous corrections.

The use of a digital controller (controller 104) which extends the capabilities of the phase detector, guarantees that this system will pick the best possible tap for coarse lock and will always lock to the correct clock edge. This assumes that the phase error between the clocks is smaller than the dynamic range of the system. In other words, DLL 100 will never saturate its hierarchical delay line without achieving lock.

The present DLL 100 can be thought of as an all-digital phase mixer (compared to analog phase mixing DLLs) and thus can be smaller, easier to verify, easier to implement and more portable among processes.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A delay-locked loop that reduces the phase difference between to clock signals, comprising:
a digital controller;
a coarse delay coupled to said digital controller; and
a fine delay coupled to said digital controller;
wherein said coarse delay provides variable delay in increments that are larger than increments provided by said fine delay.

2. The delay-locked loop of claim 1 wherein said coarse delay includes a plurality of delay elements serially connected and the connection between each pair of adjacent delay elements comprising a tap and all of said taps are coupled to a multiplexer.

3. The delay-locked loop of claim 2 wherein said multiplexer is controlled by said controller.

4. The delay-locked loop of claim 2 wherein said multiplexer a counter is disposed between said controller and said multiplexer and signal from said counter causes the multiplexer to select one of the coarse delay taps.

5. The delay-locked loop of claim 1 further including a phase detector which receives the two clock signals to be synchronized and provides an output error signal to said controller, said error signal indicating the phase difference between the two clock signals to be synchronized.

6. The delay-locked loop of claim 3 further including a phase detector which receives the two signals to be synchronized and provides an output error signal to said controller, said error signal indicating the phase difference between the two signals to be synchronized.

7. The delay-locked loop of claim 6 wherein the controller selects the first tap from the coarse delay which results in a derived clock edge placement that produces a negative phase error less than the coarse tap delay.

8. The delay-locked loop of claim 1 wherein said fine delay includes a plurality of delay includes a plurality of delay elements.

9. The delay-locked loop of claim 1 wherein said controller first selects a coarse delay and then selects a fine delay.

10. The delay-locked loop of claim 1 further including temperature compensation circuit coupled to said fine delay.

11. An electronic system, comprising:
an integrated circuit; and
a delay-locked loop coupled to said integrated circuit, said delay-locked loop reducing the phase difference between to clock signals, comprising:
a digital controller;
a coarse delay coupled to said digital controller; and
a fine delay coupled to said digital controller;
wherein said coarse delay provides variable delay in increments that are larger than increments provided by said fine delay.

12. The electronic system of claim 11 wherein said coarse delay includes a plurality of delay elements serially connected and the connection between each pair of adjacent delay elements comprising a tap and all of said taps are coupled to a multiplexer.

13. The electronic system of claim 12 wherein said multiplexer is controlled by said controller.

14. The electronic system of claim 12 wherein said multiplexer a counter is disposed between said controller and said multiplexer and signal from said counter causes the multiplexer to select one of the coarse delay taps.

15. The electronic system of claim 11 further including a phase detector which receives the two clock signals to be synchronized and provides an output error signal to said controller, said error signal indicating the phase difference between the two clock signals to be synchronized.

16. The electronic system of claim 13 further including a phase detector which receives the two signals to be synchronized and provides an output error signal to said controller, said error signal indicating the phase difference between the two signals to be synchronized.

17. The electronic system of claim 16 wherein the controller selects the first tap from the coarse delay which results in a derived clock edge placement that produces a negative phase error less than the coarse tap delay.

18. The electronic system of claim 11 wherein said fine delay includes a plurality of delay includes a plurality of delay elements.

19. The electronic system of claim 11 wherein said controller first selects a coarse delay and then selects a fine delay.

20. The electronic system of claim 11 further including temperature compensation circuit coupled to said fine delay.

21. The electronic system of claim 11 wherein said integrated circuit comprises a microprocessor.

22. A method of synchronizing the phase difference between two clocks signals; comprising:
(a) performing a first lock stage in which coarse phase adjustments are made to one of said clock signals;
(b) performing a second lock stage in which fine phase adjustments are made to the clock signal adjusted in (a);
wherein said coarse phase adjustments are larger than said fine phase adjustments.
